(19) United States
(12) Patent Application Publication
(10) Pub. No.: US 2001/0055730 A1
(43) Pub. Date: Dec. 27, 2001

(54) Method of manufacturing a semiconductor devices, embedding material for use therewith, and semiconductor device

(75) Inventors: Takeo Ishibashi, Tokyo (JP); Takeshi Okita, Hyogo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/740,877

(22) Filed: Dec. 21, 2000

(30) Foreign Application Priority Data
Jun. 16, 2000 (JP) 2000-181359

(51) Int. Cl. G03F 7/26

(52) U.S. Cl. 430/311; 430/314; 430/316; 430/317; 430/950

(57) ABSTRACT

A method of manufacturing a semiconductor device through use of an organic polymeric material, the material having a superior embedding characteristic which enables uniform embedding without regard to density of hole patterns and realizing a high etch rate, an embedding material for use with the method and a semiconductor device. An organic polymeric material can be embedded into the hole patterns to a uniform height regardless of their density, by means of coating the material several times. Further, there is formed the organic polymeric material film 30 which is to be used for embedding hole patterns and from which a pigment component is eliminated so that the etch rate of the organic polymeric film 30 is increased. By means of applying the organic anti-reflective material film 32 over the organic polymeric material film 30, a film of uniform height can be formed through multiple stages. The interconnection trenches which do not require consideration for embedding hole patterns are formed first. As a result, there can be formed interconnection trench patterns which are to be embedded with interconnection material, and hole patterns for electrically interconnecting the interconnections to a lower conductive film.

### BACKGROUND OF THE INVENTION

1. Field of the Invention

The present invention relates to a method of manufacturing a semiconductor device, to embedding material for use therewith, and to a semiconductor device. More particularly, the present invention relates to a method of manufacturing a semiconductor device which comprises an upper conductive film laid on a lower conductive film with an insulating film sandwiched therebetween, hole patterns for electrically interconnecting the upper and lower conductive films being formed in the insulating film; to embedding material for use with the method; and to a semiconductor device.

2. Description of Related Art

In association with a recent increase in the packing density and operating speed of a semiconductor device, a decrease in the resistance of material used for interconnection patterns (hereinafter often referred to as simply “interconnection material”) becomes more important. For this reason, a variety of interconnection materials have been conceived, and dry etching of some interconnection materials is difficult. For this reason, there is employed a process of embedding interconnection material into an interconnection trench pattern which has been formed in an insulation film before hand, as well as into holes for electrically interconnecting the interconnection trench pattern and a lower conductive film.

In the above-described conventional process, hole patterns of a resist are usually formed in an insulation film through photolithography, and hole patterns are formed in an insulation film by means of etching. An organic polymeric material which acts as an anti-reflective film is applied onto the insulation film in the form of a single layer. The hole patterns are buried with the organic polymeric material, thereby preventing damage to a lower conductive film underlying the hole patterns, which would otherwise be caused by etching during the foregoing process.

Interconnection trench patterns of a resist are formed on the hole patterns by means of the photolithography technique, and interconnection trench patterns are formed in the insulation film by means of etching. At this time, hole patterns for electrically interconnecting the interconnection trench patterns and the lower conductive film can be formed in the insulation film, by means of controlling an etch depth. An interconnection pattern is formed by means of burying the interconnection trench patterns and the hole patterns with interconnection material.

The above-described conventional process of burying the hole patterns with organic polymeric material which acts as an anti-reflective film is dependent on the density of the hole patterns. Therefore, dense hole patterns differ from sparse hole patterns in terms of degree of embedding. Since the organic polymeric material serves as an anti-reflective film, the organic polymeric material is etched at a low rate. At the time of etching of an insulation film to form interconnection trench patterns, fence-like etch residues arise in the edges of the hole patterns.

### SUMMARY OF THE INVENTION

The present invention has been conceived to solve the foregoing problem and is aimed at providing a method of manufacturing a semiconductor device through use of an organic polymeric material, the material having a superior embedding characteristic which enables uniform embedding without regard to density of hole patterns and realizing a high etch rate; embedding material for use with the method; and a semiconductor device.

According to a first aspect of the present invention, there is provided a method of manufacturing a semiconductor device comprising the steps of: forming hole patterns in an insulation film sandwiched between an upper conductive film and a lower conductive film for electrically interconnecting the upper and lower conductive films; a coating of applying, a plurality of times, organic polymeric embedding material used for uniformly embedding the hole patterns; coating resist over the organic polymeric embedding material film; a resist pattern formation of forming a resist pattern used for embedding interconnection trenches with interconnection material, in the resist through exposure; an etching of etching the organic polymeric embedding material film and the insulation film a predetermined number of times while the resist pattern is taken as a mask; and removing the resist and the organic polymeric embedding material, which have been left in the step of the etching.

According to a second aspect of the present invention, there is provided a method of manufacturing a semiconductor device comprising the steps of: a hole pattern formation of forming hole patterns in an insulation film sandwiched between an upper conductive film and a lower conductive film, for electrically interconnecting the upper and lower conductive films; an organic polymeric embedding material coating of coating an organic polymeric embedding material used for uniformly embedding the hole patterns; coating an organic anti-reflective film over the organic polymeric embedding material film; coating a resist over the organic anti-reflective film; coating a resist pattern used for embedding interconnection trenches with embedding material on the resist through exposure; an etching of etching the organic anti-reflective film, the organic polymeric embedding material film and the insulation film a predetermined number of times while the resist pattern is taken as a mask; and removing the resist, the organic anti-reflective film and the organic polymeric embedding material, which have been left in the step of the etching, wherein the organic polymeric embedding material does not absorb the wavelength of exposing radiation used at the time of formation of the resist pattern, and the organic anti-reflective film absorbs the wavelength of exposing radiation.

According to a third aspect of the present invention, there is provided a method of manufacturing a semiconductor device comprising the steps of: coating an insulation film laid on a lower conductive film with resist; forming on the resist, through exposure, a resist pattern for interconnection trenches; forming the interconnection trench pattern in the insulation film by means of etching the insulation film while the resist pattern is taken as a mask; a coating of applying, a plurality of times, organic polymeric embedding material used for uniformly embedding the hole patterns; coating a resist over the organic polymeric embedding material film; a hole pattern formation of forming hole patterns in the resist through exposure, the hole patterns being in the insulation film sandwiched between an upper conductive film and a lower conductive film, for electrically interconnecting the upper conductive film and the lower conductive film; an etching of etching the organic polymeric embedding material film and the insulation film while the hole patterns are taken as masks; and a removing of removing the resist and the organic polymeric embedding material, which have been left in the etching step.

According to a fourth aspect of the present invention, there is provided an organic polymeric embedding material for use in the method of manufacturing a semiconductor material according to any one of the aspects of the present invention, in which the material does not absorb the wavelength of exposing radiation used at the time of formation of the resist pattern, and does not dissolve and is not dissolved in the organic anti-reflective film.

According to a fifth aspect of the present invention, there is provided a semiconductor device manufactured by the method of manufacturing a semiconductor device according to any one of the aspects of the present invention.

The above and other objects, effects, features and advantages of the present invention will become more apparent from the following description of the embodiments thereof taken in conjunction with the accompanying drawings.

### BRIEF DESCRIPTION OF THE DRAWINGS

FIGS. 1A through 1G illustrate the cross-sectional structure of hole patterns formed in a semiconductor substrate according to a first embodiment of the present invention.

FIGS. 2A through 2G illustrate the cross-sectional structure of hole patterns formed in a semiconductor substrate according to a second embodiment of the present invention.

FIGS. 3A through 3G illustrate the cross-sectional structure of respective hole patterns formed in a semiconductor substrate according to a third embodiment of the present invention.

FIG. 4 shows an example pigment component; that is, a common pigment example (an anthracene derivative) for KrF exposing radiation (248 nm).

FIG. 5 shows anti-reflection capability relative to pigment content, wherein the vertical axis represents anti-reflection capability and the horizontal axis represents pigment content.

FIG. 6 shows etch rate relative to pigment content, wherein the vertical axis represents etch rate and the horizontal axis represents pigment content.

FIG. 7 shows a fence-like residue which would be induced when an organic anti-reflective material is used for embedding purpose.

### DETAILED DESCRIPTION OF THE PREFERRED EMBODIMENTS

Embodiments of the present invention will be described below with reference to the accompanying drawings. It is noted that the same reference symbols in the drawings denote the same or corresponding components.

First Embodiment

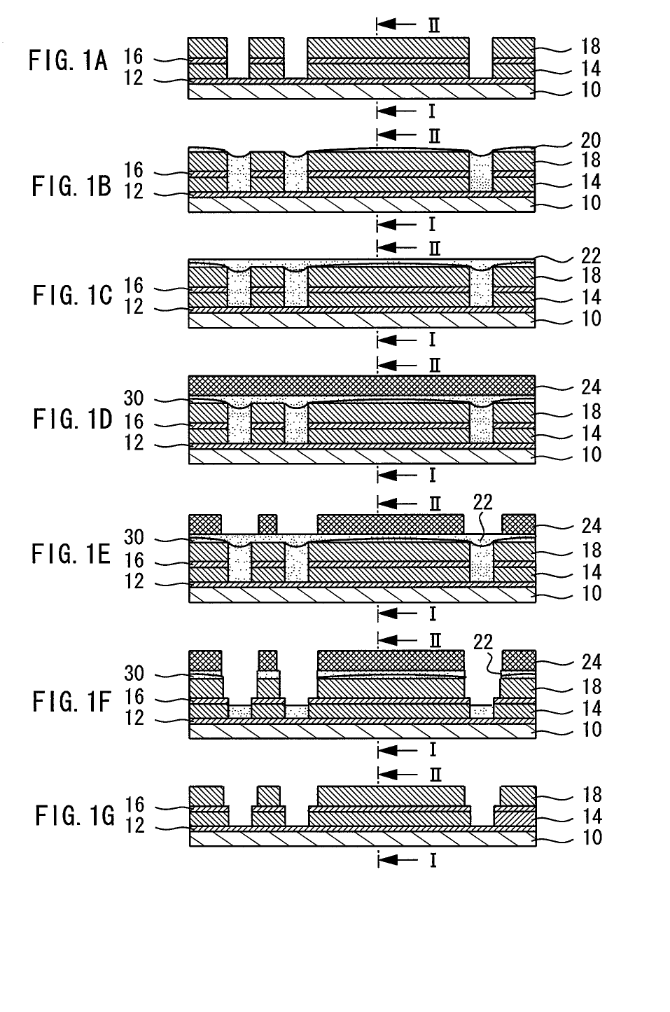

FIGS. 1A through 1G illustrate the cross-sectional structure of hole patterns formed in a semiconductor substrate according to a first embodiment of the present invention. In FIGS. 1A through 1G, reference numeral 10 designates a lower conductive film; 12 designates a protective film for protecting the lower conductive film 10 at the time of etching of hole patterns; 14 designates an insulation film formed on the protective film 12; 16 designates an etch stopper film for stopping etching of an interconnection trench pattern; and 18 designates an insulation film formed on the etch stopper film 16. Broken lines between reference numerals I and II designate a cutting line.

As shown in FIG. 1B, an organic polymeric material film 20 is formed by means of applying organic polymeric material several times in order to bury hole patterns. Preferably, the organic polymeric material film 20 is formed to a thickness of about 50 nm to 1500 nm.

As shown in FIG. 1C, there is formed an organic anti-reflective film 22 which has a superior embedding characteristic and whose top surface is of uniform height regardless of whether hole patterns are dense or sparse. The organic anti-reflective film 22 absorbs exposing radiation used in a subsequent step of forming a resist pattern. Preferably, the organic anti-reflective film 22 is formed to a thickness of about 50 nm to 1500 nm.

As shown in FIG. 1D, resist 24 is applied over the organic anti-reflective film 22, preferably to a thickness of about 500 nm to 1500 nm. The resist 24 can be applied by means of spin coating or a like technique. The semiconductor substrate is subjected to baking (or heat treatment) at a temperature of, for example, 80° C. through 150° C., for about 60 seconds, to thereby evaporate the solvent contained in the resist.

In order to form a resist pattern for interconnection trenches, the semiconductor substrate is exposed to a light source whose wavelength corresponds to a resist sensitizing wavelength, such as I-lines, a KrF excimer laser, or an ArF excimer laser.

After exposure, the semiconductor substrate is subjected to a post exposure baking (PEB) operation for 60 seconds or thereabouts at a temperature of, for example, 80° C. through 120° C., to thereby improve the resolution of the resist 24. The thus-exposed resist 24 is developed through use of an about 2.00% to 2.50% alkaline solution, such as tetra methyl ammonium hydroxide. The semiconductor substrate is subjected to heat treatment (PDB) for 60 seconds or thereabouts at a temperature of, for example, 100° C. through 130° C., as required, thereby hardening the resist pattern for an interconnection trench. As a result, there is formed a resist pattern as shown in FIG. 1E.

As shown in FIG. 1F, the organic polymeric material film 20, the organic anti-reflective film 22, and the insulation film 18 are etched by one operation while the resist pattern formed in the manner as mentioned above is used as a mask. Alternatively, the organic polymeric material film 20 and the organic anti-reflective film 22 are etched first. Subsequently, the insulation film 18 can be etched. In any event, during an etching operation, presence of the etch stopper film 12 prevents etching of the insulation film 14 underlying the etch stopper film 12.

Finally, as shown in FIG. 1G, there are removed the resist film 24, the organic polymeric material film 20, and the organic anti-reflective film 22, which have remained after etching. As a result, interconnection trench patterns which are to be embedded with interconnection material, and hole patterns for electrically interconnecting the interconnections to the lower conductive film 10 can be formed in the insulation films 14 and 18.

According to the first embodiment, an organic polymeric material can be embedded into the hole patterns to a uniform height regardless of their density, by means of coating the material several times. Therefore, there can be formed interconnection trench patterns which are to be embedded with interconnection material, and hole patterns for electrically interconnecting the interconnections and the lower conductive film 10.

Second Embodiment

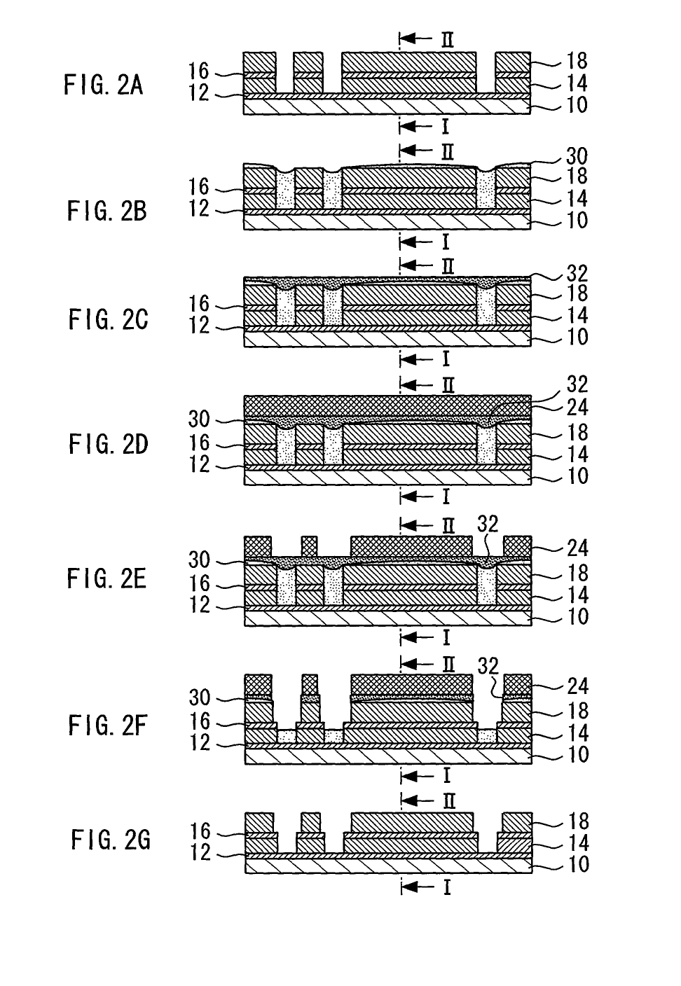

FIGS. 2A through 2G illustrate the cross-sectional structure of hole patterns formed in a semiconductor substrate according to a second embodiment of the present invention. In FIGS. 2A through 2G, those reference numerals which are the same as those shown in FIGS. 1A through 1G designate the same elements, and hence repetition of their explanations is omitted.

FIG. 2A is identical with FIG. 1A, and hence its explanation is omitted. As shown in FIG. 2B, in order to embed hole patterns, an organic polymeric material is applied to a semiconductor substrate, to thereby form an organic polymeric material film 30, preferably to a thickness of about 30 nm to 50 nm. The organic polymeric material can be applied to a semiconductor substrate by means of spin coating. The semiconductor substrate is subjected to baking (heat treatment) for 60 seconds or thereabouts at a temperature of, for example, 180° C. through 220° C., to thereby evaporate the solvent contained in the organic polymeric material film 30. If the organic polymeric material has been poorly embedded in the hole patterns, application of the organic polymeric material is further repeated several times, to thereby improve the embedding characteristic of the organic polymeric material.

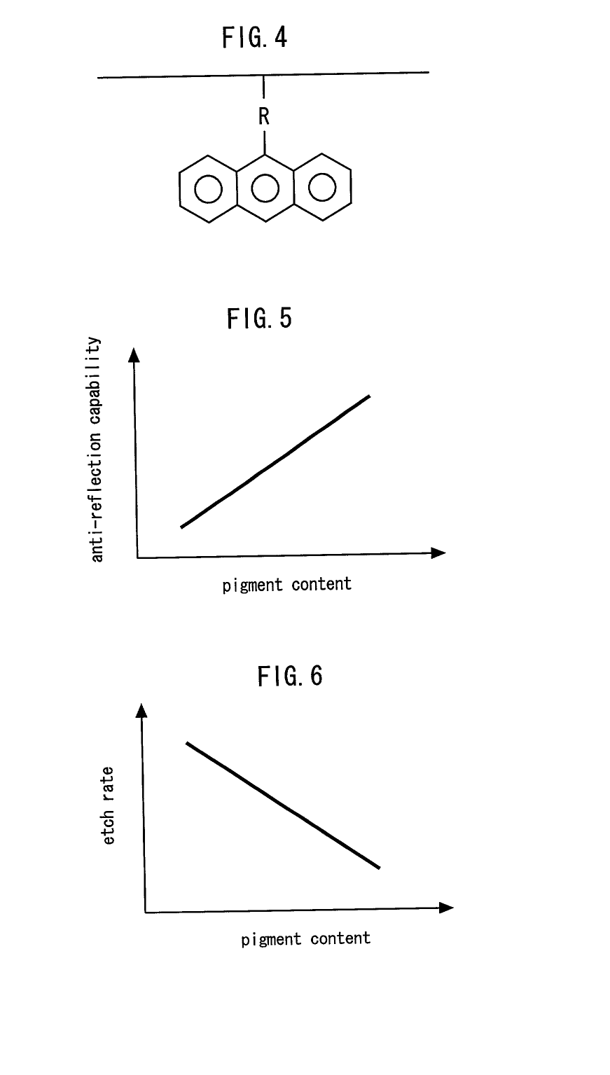

A pigment component, which absorbs the wavelength of exposing radiation which is to be used in a subsequent step of forming a resist pattern through photolithography, is eliminated from the organic polymeric material 30. FIG. 4 shows an example pigment component; that is, a common pigment example (an anthracene derivative) for KrF exposing radiation (248 nm). Elimination of a pigment component that absorbs the wavelength of exposing radiation enables an increase in an etch rate during an etching operation.

For a lithography which employs UV rays as exposure radiation, aromatic compounds having a π-π* absorption characteristic or compounds containing a diazo-based functional group or a carbolic functional group, the group having an n-π* absorption characteristic, are usually used as pigment contained in an organic anti-reflective material. FIG. 5 shows anti-reflection capability relative to pigment content, wherein the vertical axis represents anti-reflection capability and the horizontal axis represents pigment content. As shown in FIG. 5, the greater the pigment content, the higher the anti-reflection capability. FIG. 6 shows etch rate relative to pigment content, wherein the vertical axis represents etch rate and the horizontal axis represents pigment content. As shown in FIG. 6, the greater the pigment content, the lower the etch rate. The foregoing compounds has a large pigment content and, hence, are etched at a slow rate by means of dry etching. In either the first embodiment or a third embodiment which will be described later, if material used for embedding is etched slowly, the following problem will arise.

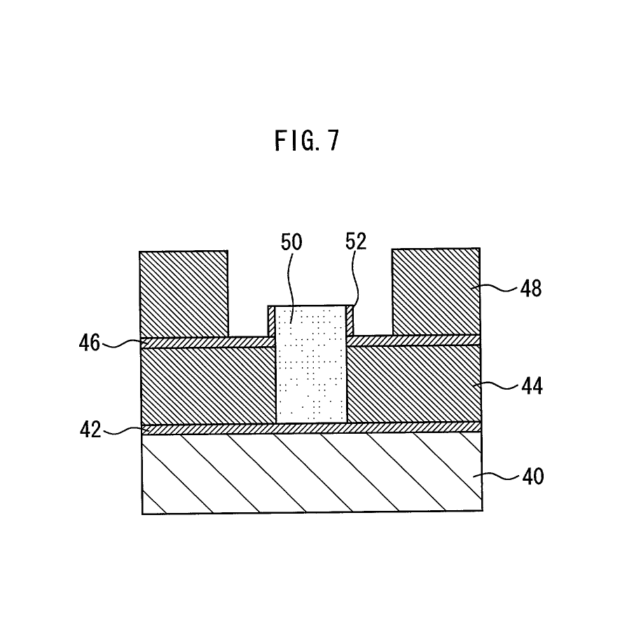

FIG. 7 shows a fence-like residue which would be induced when an organic anti-reflective material is used for embedding purpose. In FIG. 7, reference numeral 40 designates Cu; 42 designates a Cu protective film for protecting a Cu layer 40; 44 designates an insulation film laid on the Cu protective film 42; 46 designates an etch stopper film laid on the insulation film 44; 48 designates an insulation film laid on the etch stopper film 46; 50 designates an organic anti-reflection material; and 52 designates a fence-like residue. As shown in FIG. 7, if an embedded material is etched slowly, the first embodiment encounters occurrence of the fence-like residue 52 around the periphery of each of holes. In contrast, in the third embodiment an embedded film per se is etched during dry etching of holes, as will be described later. For this reason, resist of a resist pattern which is to be formed in an upper layer must be formed thick.

To this end, the molecular weight of organic polymeric material 30 (embedding material) is reduced, to thereby increase the fluidity of the organic polymeric material when the material is cross-linked through heat treatment. Thus, the characteristic of the organic polymeric material being embedded into the hole patterns is improved. Further, the embedding material has a characteristic of not being dissolved in the organic anti-reflective film 32, which is to be applied after embedding of the embedding material. An example embedding material is formed by means of dissolving, with an acetate-based solvent, acrylic polymer having a weight-average molecular weight of 4000, a cross-linking agent containing an alkoxylmethylamino group, and a sulfonic-acid-based acid catalyst.

As shown in FIG. 2C, organic anti-reflection material is applied over the organic polymeric material film 30, to thereby form an organic anti-reflective film 32, preferably to a thickness of about 50 nm through 1500 nm. The organic anti-reflective film 32 absorbs the wavelength of exposing radiation used in a subsequent step of forming a resist pattern. As in the case of the organic polymeric material 30 used for burying hole patterns, the organic anti-reflective film 32 can be applied by means of spin coating or a like technique. For example, the semiconductor substrate is subjected to baking (heat treatment) for about 60 seconds at a temperature of, for example, 180° C. through 220° C., thereby evaporating the solvent contained in the organic anti-reflective material.

As shown in FIG. 2D, the resist 24 is applied over the organic anti-reflective film 32, preferably to a thickness of about 500 nm through 1500 nm. The resist 24 can be applied by means of spin coating or a like technique. For example, the semiconductor substrate is subjected to baking (heat treatment) at a temperature of, for example, 80° C. through 150° C., to thereby evaporate the solvent contained in the resist 24.

Next, in order to form a resist pattern for an interconnection trench, the semiconductor substrate is exposed through use of a light source whose wavelength corresponds to a resist sensitizing wavelength, e.g., I-lines, a KrF excimer laser, or an ArF excimer laser.

After exposure of the resist 24, the semiconductor substrate is subjected to a post exposure baking (PEB) operation for 60 seconds or thereabouts at a temperature of, for example, 80° C. through 120° C., to thereby improve the resolution of the resist 24. The thus-exposed resist 24 is developed through use of an about 2.00% to 2.50% alkaline solution, such as tetra methyl ammonium hydroxide (TMAH). The semiconductor substrate is subjected to heat treatment (PDB) for 60 seconds or thereabouts at a temperature of, for example, 100° C. through 130° C., as required, thereby hardening the resist pattern for an interconnection trench. As a result, there is formed a resist pattern as shown in FIG. 2E.

As shown in FIG. 2F, the organic anti-reflective material film 32 formed in the manner as mentioned above, the organic polymeric material film 30 used for embedding hole patterns, and the insulation film 18 are etched in a single operation. Alternatively, the organic anti-reflective film 32 and the organic polymeric material film 30 used for embedding hole patterns are etched first. Subsequently, the insulation film 18 can be etched. Since a pigment component is eliminated from the organic polymeric material 30 used for embedding, the organic polymeric material 30 is etched fast. Accordingly, the height of an embedded material is controlled so as to become lower than the etching stopper film 16. At the time of an etching operation, presence of the etch stopper film 12 prevents etching of the insulation film 14 underlying the etch stopper film 12.

Finally, as shown in FIG. 2G, there are removed the resist film 24, the organic anti-reflective film 32, and the organic polymeric material film 30 used for embedding, which have remained after etching. As a result, interconnection trench patterns which are to be embedded with interconnection material, and hole patterns for electrically interconnecting the interconnections to the lower conductive film 10 can be formed in the insulation films 14 and 18.

According to the second embodiment, there is formed the organic polymeric material film 30 which is to be used for embedding hole patterns and from which a pigment component is eliminated so that the etch rate of the organic polymeric film 30 is increased. By means of applying the organic anti-reflective material film 32 over the organic polymeric material film 30, a film of uniform height can be formed through multiple stages. Accordingly, there is formed an interconnection trench pattern used for embedding interconnection material and hole patterns for electrically interconnecting the interconnection and the lower conductive film 10.

Third Embodiment

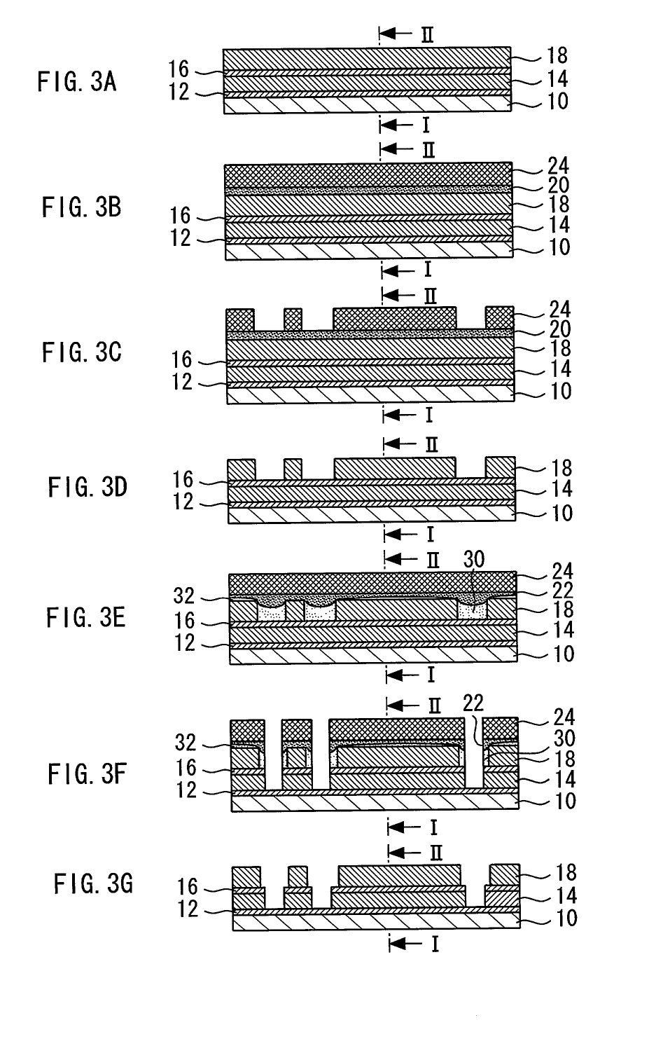

FIGS. 3A through 3G illustrate the cross-sectional structure of respective hole patterns formed in a semiconductor substrate according to a third embodiment of the present invention. In FIGS. 3A through 3G, those reference numerals which are the same as those shown in FIGS. 1A through 1G designate the same elements, and hence repetition of their explanations is omitted.

As shown in FIG. 3A, in contrast with the hole patterns formed in the semiconductor substrates described in connection with the first and second embodiments, no hole patterns are formed in a semiconductor substrate employed in the third embodiment. As shown in FIG. 3B, an organic polymeric embedding material film 20 is formed, preferably to a thickness of 50 nm through 1500 nm, by means of applying organic polymeric embedding material over the insulation film 18 several times. The organic polymeric material film 20 can be applied by means of spin coating or a like technique. The semiconductor substrate is subjected to baking (heat treatment) for 60 seconds or thereabouts at a temperature of, for example, 180° C. through 220° C., to thereby evaporate the solvent contained in the organic polymeric material. Next, the resist 24 is applied over the organic polymeric material film 20, preferably to a thickness of about 500 nm through 1500 nm. The resist 24 can be applied by means of spin coating or a like technique. For example, the semiconductor substrate is subjected to baking (heat treatment) at a temperature of, for example, 80° C. through 150° C., to thereby evaporate the solvent contained in the resist 24.

In order to form a resist pattern for an interconnection trench, the semiconductor substrate is exposed through use of a light source whose wavelength corresponds to a resist sensitizing wavelength; e.g., I-lines, a KrF excimer laser, or an ArF excimer laser.

After exposure of the resist 24, the semiconductor substrate is subjected to a post exposure baking (PEB) operation for 60 seconds or thereabouts at a temperature of, for example, 80° C. through 120° C., to thereby improve the resolution of the resist 24. The thus-exposed resist 24 is developed through use of an about 2.00% to 2.50% alkaline solution, such as tetra methyl ammonium hydroxide (TMAH). The semiconductor substrate is subjected to heat treatment (PDB) for 60 seconds or thereabouts at a temperature of, for example, 100° C. through 130° C., as required, thereby hardening the resist pattern for an interconnection trench. As a result, there is formed a resist pattern as shown in FIG. 3C.

As shown in FIG. 3D, the insulation film 18 is etched while the resist pattern formed according to the foregoing method is used as a mask. At this time, presence of the etch stopper film 16 prevents etching of the insulation film 14 underlying the etch stopper film 16. Subsequently, the remaining resist 24 and the organic polymeric material film 20 are removed. In this way, an interconnection trench pattern which is to be buried with embedding material can be formed in the insulation film 18.

As shown in FIG. 3E, in order to embed interconnection trench patterns, an organic polymeric material is applied to a semiconductor substrate, to thereby form an organic polymeric material film 30, preferably to a thickness of about 30 nm to 50 nm. The organic polymeric material 30 may or may not absorb the wavelength of exposing radiation which is to be used in a subsequent step of forming a resist pattern. The organic polymeric material 30 can be applied to a semiconductor substrate by means of spin coating. The semiconductor substrate is subjected to baking (heat treatment) for 60 seconds or thereabouts at a temperature of, for example, 180° C. through 220° C., to thereby evaporate the solvent contained in the organic polymeric material film 30. If the organic polymeric material has been poorly embedded in the hole patterns, application of the organic polymeric material is further repeated several times, to thereby improve the embedding characteristic of the organic polymeric material.

Organic anti-reflection material is applied over the organic polymeric material film 30, to thereby form the organic anti-reflective film 22, preferably to a thickness of about 50 nm through 1500 nm. The organic anti-reflective film 32 absorbs the wavelength of exposing radiation used in a subsequent step of forming a resist pattern. The organic anti-reflection film 22 absorbs the wavelength of exposing radiation which is to be used in a subsequent step of forming a resist pattern. As in the case of the organic polymeric material 30 used for burying hole patterns, the organic anti-reflective film 22 can be applied by means of spin coating or a like technique. For example, the semiconductor substrate is subjected to baking (heat treatment) for about 60 seconds at a temperature of, for example, 180° C. through 220° C., thereby evaporating the solvent contained in the organic anti-reflective material.

Next, the resist 24 is applied over the organic anti-reflective film 22, preferably to a thickness of about 500 nm through 1500 nm. The resist 24 can be applied by means of spin coating or a like technique. For example, the semiconductor substrate is subjected to baking (heat treatment) at a temperature of, for example, 80° C. through 150° C., to thereby evaporate the solvent contained in the resist 24.

Next, in order to form a resist pattern for an interconnection trench, the semiconductor substrate is exposed through use of a light source whose wavelength corresponds to a resist sensitizing wavelength; e.g., I-lines, a KrF excimer laser, or an ArF excimer laser.

After exposure of the resist 24, the semiconductor substrate is subjected to a post exposure baking (PEB) operation for 60 seconds or thereabouts at a temperature of, for example, 80° C. through 120° C., to thereby improve the resolution of the resist 24. The thus-exposed resist 24 is developed through use of an about 2.00% to 2.50% alkaline solution, such as tetra methyl ammonium hydroxide (TMAH). The semiconductor substrate is subjected to heat treatment (PDB) for 60 seconds or thereabouts at a temperature of, for example, 100° C. through 130° C., as required, thereby hardening the resist pattern for an interconnection trench.

As shown in FIG. 3F, the insulation film 18 is etched while the resist pattern formed in the manner as mentioned above is taken as a mask. At this time, the embedding material 30 serves as a film to be etched. If the embedding material 30 does not contain a pigment component which absorbs the wavelength of an exposing radiation, the embedding material 30 will be advantageously etched faster. Subsequently, the remaining resist 24 and the organic anti-reflective film 22 are removed.

As shown in FIG. 3G, interconnection trench patterns which are to be embedded with interconnection material, and hole patterns for electrically interconnecting the interconnections to the lower conductive film 10 can be formed in the insulation films 14 and 18.

According to the third embodiment, interconnection trenches which do not require consideration for embedding hole patterns are formed first. As a result, there can be formed interconnection trench patterns which are to be embedded with interconnection material, and hole patterns for electrically interconnecting the interconnections to a lower conductive film.

As mentioned above, according to the method of manufacturing a semiconductor device, the embedding material for use with the method, and the semiconductor device, all pertaining to the present invention, organic polymeric material can be embedded in hole patterns to a uniform height regardless of density of the hole patterns, by means of applying the organic polymeric material to the hole patterns several times. As a result, there can be formed interconnection trench patterns which are to be embedded with interconnection material, and hole patterns for electrically interconnecting the interconnections to a lower conductive film. The present invention can provide a method of manufacturing a semiconductor device through use of an organic polymeric material, the material having a superior embedding characteristic which enables embedding of embedding material to a uniform height without regard to density of hole patterns and which realizes a high etch rate; embedding material for use with the method; and a semiconductor device.

In the method of manufacturing a semiconductor device, the coating step may comprise the steps of: coating an organic polymeric embedding material used for uniformly embedding the hole patterns, and coating an organic anti-reflective film which absorbs the wavelength of exposing radiation which is to be used in the step of the hole pattern formation; wherein, the step of the etching involves etching of the organic anti-reflective film, the organic polymeric embedding material film and the insulation film while the resist pattern is taken as a mask; and the step of the removal involves removal of the resist, the organic anti-reflective film and the organic polymeric embedding material, which have been left in the etching step.

In the method of manufacturing a semiconductor device, the step of the coating the organic polymeric embedding material may employ organic polymeric material which does not contain any aromatic compounds.

In the method of manufacturing a semiconductor device, in the step of the coating the organic polymeric embedding material, after having been applied by means of spin coating, the organic polymeric material may be baked a plurality of times.

In the method of manufacturing a semiconductor device, the organic polymeric material used in the step of the coating the organic polymeric embedding material may be not dissolved in and may not dissolve the organic anti-reflective film.

In the method of manufacturing a semiconductor device, the organic polymeric material used in the step of the coating the organic polymeric embedding material may attain high fluidity when cross-linked by means of heat treatment and has a low molecular weight.

In the method of manufacturing a semiconductor device, the organic polymeric material used in the step of the coating the organic polymeric embedding material may have a high thermo-setting temperature.

In the organic polymeric embedding material, the organic polymeric embedding material may attain high fluidity when cross-linked by means of heat treatment and has a low molecular weight.

In the organic polymeric embedding material, the organic polymeric embedding material has a high thermo-setting temperature.

The present invention has been described in detail with respect to various embodiments, and it will now be apparent from the foregoing to those skilled in the art that changes and modifications may be made without departing from the invention in its broader aspects, and it is the invention, therefore, in the appended claims to cover all such changes and modifications as fall within the true spirit of the invention.

The entire disclosure of Japanese Patent Application No. 2000-181359 filed on Jun. 16, 2000 including specification, claims, drawings and summary are incorporated herein by reference in its entirety.

What is claimed is:

1. A method of manufacturing a semiconductor device comprising the steps of:
forming hole patterns in an insulation film sandwiched between an upper conductive film and a lower conductive film for electrically interconnecting the upper and lower conductive films;
a coating of applying, a plurality of times, organic polymeric embedding material used for uniformly embedding the hole patterns;
coating resist over the organic polymeric embedding material film;
a resist pattern formation of forming a resist pattern used for embedding interconnection trenches with interconnection material, in the resist through exposure;
an etching of etching the organic polymeric embedding material film and the insulation film a predetermined number of times while the resist pattern is taken as a mask; and
removing the resist and the organic polymeric embedding material, which have been left in said step of the etching.

2. The method of manufacturing a semiconductor device according to claim 1, wherein said step of the coating comprises the steps of:
coating an organic polymeric embedding material used for uniformly embedding the hole patterns; and
coating an organic anti-reflective film which absorbs the wavelength of exposing radiation which is to be used in said step of the resist pattern formation.

3. The method of manufacturing a semiconductor device according to claim 1, wherein said step of the coating the organic polymeric embedding material employs organic polymeric material which does not contain any aromatic compounds.

4. The method of manufacturing a semiconductor device according to claim 1, wherein, in said step of the coating the organic polymeric embedding material, after having been applied by means of spin coating, the organic polymeric material is baked a plurality of times.

5. The method of manufacturing a semiconductor device according to claim 1, wherein the organic polymeric material used in said step of the coating the organic polymeric embedding material is not dissolved in and does not dissolve the organic anti-reflective film.

6. The method of manufacturing a semiconductor device according to claim 1, wherein the organic polymeric material used in said step of the coating the organic polymeric embedding material attains high fluidity when cross-linked by means of heat treatment and has a low molecular weight.

7. The method of manufacturing a semiconductor device according to claim 1, wherein the organic polymeric material used in said step of the coating the organic polymeric embedding material has a high thermo-setting temperature.

8. A method of manufacturing a semiconductor device comprising the steps of:
a hole pattern formation of forming hole patterns in an insulation film sandwiched between an upper conductive film and a lower conductive film, for electrically interconnecting the upper and lower conductive films;
an organic polymeric embedding material coating of coating an organic polymeric embedding material used for uniformly embedding the hole patterns;
coating an organic anti-reflective film over the organic polymeric embedding material film;
coating a resist over the organic anti-reflective film;
coating a resist pattern used for embedding interconnection trenches with embedding material on the resist through exposure;
an etching of etching the organic anti-reflective film, the organic polymeric embedding material film and the insulation film a predetermined number of times while the resist pattern is taken as a mask; and
removing the resist, the organic anti-reflective film and the organic polymeric embedding material, which have been left in said step of the etching, wherein
the organic polymeric embedding material does not absorb the wavelength of exposing radiation used at the time of formation of the resist pattern, and the organic anti-reflective film absorbs the wavelength of exposing radiation.

9. The method of manufacturing a semiconductor device according to claim 8, wherein said step of the coating the organic polymeric embedding material employs organic polymeric material which does not contain any aromatic compounds.

10. The method of manufacturing a semiconductor device according to claim 8, wherein, in said step of the coating the organic polymeric embedding material, after having been applied by means of spin coating, the organic polymeric material is baked a plurality of times.

11. The method of manufacturing a semiconductor device according to claim 8, wherein the organic polymeric material used in said step of the coating the organic polymeric embedding material is not dissolved in and does not dissolve the organic anti-reflective film.

12. The method of manufacturing a semiconductor device according to claim 8, wherein the organic polymeric material used in said step of the coating the organic polymeric embedding material attains high fluidity when cross-linked by means of heat treatment and has a low molecular weight.

13. The method of manufacturing a semiconductor device according to claim 8, wherein the organic polymeric material used in said step of the coating the organic polymeric embedding material has a high thermo-setting temperature.

14. A method of manufacturing a semiconductor device comprising the steps of:
coating an insulation film laid on a lower conductive film with resist;
forming on the resist, through exposure, a resist pattern for interconnection trenches;
forming the interconnection trench pattern in the insulation film by means of etching the insulation film while the resist pattern is taken as a mask;
a coating of applying, a plurality of times, organic polymeric embedding material used for uniformly embedding the hole patterns;
coating a resist over the organic polymeric embedding material film;
a hole pattern formation of forming hole patterns in the resist through exposure, the hole patterns being in the insulation film sandwiched between an upper conductive film and a lower conductive film, for electrically interconnecting the upper conductive film and the lower conductive film;
an etching of etching the organic polymeric embedding material film and the insulation film while the hole patterns are taken as masks; and
a removal of removing the resist and the organic polymeric embedding material, which have been left in the etching step.

15. The method of manufacturing a semiconductor device according to claim 14, wherein the coating step comprises the steps of:
coating an organic polymeric embedding material used for uniformly embedding the hole patterns, and
coating an organic anti-reflective film which absorbs the wavelength of exposing radiation which is to be used in said step of the hole pattern formation;
wherein,
said step of the etching involves etching of the organic anti-reflective film, the organic polymeric embedding material film and the insulation film while the resist pattern is taken as a mask; and
said step of the removal involves removal of the resist, the organic anti-reflective film and the organic polymeric embedding material, which have been left in the etching step.

16. The method of manufacturing a semiconductor device according to claim 14, wherein said step of the coating the organic polymeric embedding material employs organic polymeric material which does not contain any aromatic compounds.

17. The method of manufacturing a semiconductor device according to claim 14, wherein, in said step of the coating the organic polymeric embedding material, after having been applied by means of spin coating, the organic polymeric material is baked a plurality of times.

18. The method of manufacturing a semiconductor device according to claim 14, wherein the organic polymeric material used in said step of the coating the organic polymeric embedding material is not dissolved in and does not dissolve the organic anti-reflective film.

19. The method of manufacturing a semiconductor device according to claim 14, wherein the organic polymeric material used in said step of the coating the organic polymeric embedding material attains high fluidity when cross-linked by means of heat treatment and has a low molecular weight.

20. The method of manufacturing a semiconductor device according to claim 14, wherein the organic polymeric material used in said step of the coating the organic polymeric embedding material has a high thermo-setting temperature.
